(19) United States
(12) Patent Application Publication
(10) Pub. No.: US 2015/0103036 A1
(43) Pub. Date: Apr. 16, 2015

(54) IN-CELL TOUCH DEVICE AND MANUFACTURING METHOD THEREOF

(71) Applicants: BOE Technology Group Co., Ltd., Beijing (CN); Chengdu BOE Optoelectronics Technology Co., Ltd., Chengdu, Sichuan Province (CN)

(72) Inventors: Xiangdan Dong, Beijing (CN); Young Yik Ko, Beijing (CN); Minghua Xuan, Beijing (CN); Weiyun Huang, Beijing (CN); Yue Long, Beijing (CN)

(21) Appl. No.: 14/349,869

(22) PCT Filed: Dec. 13, 2013
(86) PCT No.: PCT/CN2013/089313

§ 371 Date: Apr. 4, 2014

(30) Foreign Application Priority Data
May 31, 2013 (CN) 201310215576.5

(51) Int. Cl. G06F 3/041; H01L 27/12

(52) U.S. Cl. CPC G06F 3/0412; G06F 3/0416; H01L 27/1259; G06F 2203/04103
USPC 345/174; 438/29

(57) ABSTRACT

The present invention provides an in-cell touch device and a manufacturing method thereof. The in-cell touch device comprises: a color filter substrate, an array substrate, and an integration circuit, wherein conductive pads are arranged at the edges of each line and each column of the sensors in the sensor pattern on the color filter substrate, and conductive pads are arranged on the array substrate at the positions corresponding to the color filter substrate, wherein the conductive pads are formed in the transparent conductive layer, the conductive pads arranged on the color filter substrate are connected to the pads arranged at the corresponding positions on the array substrate with conductive guiding material, and the conductive pads arranged on the array substrate are connected to the integration circuit with metal wires, and wherein, the sensors communicate signals with the integration circuit in turns through the conductive pads arranged on the color filter substrate, the conductive guiding material, the conductive pads arranged on the array substrate, and the metal wires. It may effectively reduce the transmission resistance during the signal transmission by adopting technical solution provided in the present disclosure.

### TECHNICAL FIELD

The present invention relates to a field of touch screen technology, and particular to an in-cell touch device and a manufacturing method thereof.

### BACKGROUND

Touch screen is a type of induction crystal display device. When a finger touches the graphic button on the screen, the touch feedback system on the screen may drive a variety of connecting devices based on a pre-scheduled program, which replaces the mechanical button panel, and creates vivid media effects by crystal display images. As one of the latest computer input devices, the touch screen currently is the simplest, convenient, and natural way of the human-computer interaction device, and it also marks the real arrival of the universal time of the computer application. From a view of technical principle, the touch screen is a set of transparent absolute-positioning system. Firstly, the touching action of the finger is detected and the touch position of the finger is determined, and then the detected and determined results are input into a pre-scheduled program by the touch feedback system, such as a sensor, to drive a variety of connecting device, and corresponding actions are triggered.

According to the positions of the sensors in the touch screen, the touch screen may be divided to in-cell touch screen, out-cell touch screen, and on-cell touch screen. Wherein, in general, the existing touch screens are mainly based on the out-cell touch screen and the on-cell touch screen. Considering the light and thin requirement of the mobile terminal, the in-cell touch screen application will be in trend. Here, the main body of the in-cell touch screen is formed by cell assembling a glass substrate covered with color filter (CF) and a glass substrate deposited with thin film transistors (TFT) and then grain filling, and meanwhile placing the sensors in the cell. Hereinafter, the glass substrate covered with the CF is referred to as CF substrate, and the glass substrate deposited with TFT is referred to as array substrate.

FIG. 1a is a structure diagram of the CF substrate of the in-cell touch screen in the prior art. FIG. 1b is a structure diagram of the array substrate in the prior in-cell technology. As shown in FIG. 1a and FIG. 1b, the sensors 2 are arranged on the CF substrate 1, all the sensors 2 form a sensor pattern, all conductive pads 3 arranged on the CF substrate 1 are located under the sensor patter; each of the sensors 2 at different positions passing through the circuit wirings 4 of the indium tin oxide (ITO) layer are connected to each of the conductive pads 3 with numerals of a, b, c, d, e, f and g, respectively. Accordingly, seven conductive pads 3 with numeral of a′, b′, c′, d′, e′, f′ and g′ are arranged on the array substrate 5 at the positions corresponding to the each of the conductive pads 3 on the CF substrate 1. Meanwhile all the pads 3 on the array substrate 5 are connected with an integration circuit (IC) 6 for processing touch signal. In this design solution, since all the conductive pads 3 arranged on the CF substrate 1 are located focally under the sensor pattern. In this way, the signal transmission between the sensor 2 and the IC 6 needs to be realized through a longer circuit wirings 4 of the ITO layer, and thus, the resistance of the wirings between the sensors 2 and the conductive pads 3 arranged on the CF substrate 1 is higher, and thereby causes the large power consuming and difficult to dissipate heat.

A technical solution for reducing the transmission resistance in the prior art is to additionally arrange a metal layer on the CF substrate, adopt circuit wirings in the metal layer, to communicate signals between the sensors and the conductive pads on the CF substrate. However, this solution increases the process steps.

### SUMMARY

To this end, the main object of the present invention is to provide an in-cell touch device and a manufacturing method thereof which may effectively reduce the transmission resistance during the transmission.

To achieve the above object, the present invention provides an in-cell touch device comprising: a CF substrate, an array substrate, and an integration circuit (IC); conductive pads arranged on the edges of each line and each column of the sensors in the sensor pattern on the CF substrate, and conductive pads arranged on the array substrate at positions corresponding to those conductive pads on the CF substrate; wherein the conductive pads are formed in the transparent conductive layers of the CF substrate and the array substrate, the conductive pads arranged on the CF substrate are connected to the conductive pads at the corresponding positions on the array substrate with conductive guiding material, and the conductive pads arranged on the array substrate are connected to the integration circuit with metal wires; and wherein the sensors are used to communicate signals with the IC in turns through the conductive pads arranged on the CF substrate, the conductive guiding material, the conductive pads arranged on the array substrate, and the metal wires.

In the above technical solution, the conductive pads are arranged at both of the left and right edges of the each line of the sensors in the sensor pattern on the CF substrate.

In the above technical solution, the IC circuit may be bound on the array substrate.

In the above technical solution, the metal wires may be metal wires that are formed from the metal layer on the array substrate.

In the above technical solution, the material of the metal layer may be selected from Mo, Al, AiNd, or AlNdMo.

The embodiments of the present invention further provide a method for manufacturing the in-cell device, comprising: arranging conductive pads at the edges of each line and each column of the sensors in the sensor pattern on a CF substrate, and arranging conductive pads on an array substrate at positions corresponding to those conductive pads on the CF substrate; wherein the conductive pads are formed in the transparent conductive layers of the CF substrate and the array substrate; connecting the conductive pads arranged on the color filter substrate to the conductive pads arranged at the corresponding positions on the array substrate with conductive guiding material, and connecting the conductive pads and the IC arranged on the array substrate with metal wires; wherein the sensors communicate signals with the IC in turns through the conductive pads arranged on the CF substrate, the conductive guiding material, the conductive pads arranged on the array substrate, and the metal material.

In the above technical solution, arranging the conductive pads at the edges of each line and each column of the sensors in the sensor pattern on the CF substrate comprises: arranging the conductive pads at both left and right edges of each line of the sensors in the sensor pattern on the CF substrate.

In the above technical solution, the method further comprises: determining the positions of the arranged conductive pads based on the dimensions of the panels and the sizes of the frames formed by the CF substrate and the array substrate when arranging the conductive pads on the CF substrate.

The in-cell touch device and the manufacturing method thereof provided in the embodiments of the present invention may effectively reduce the length of the circuit wirings of the transparent conductive layer due to the arrangement of the conductive pads at the edges of each line and each column of sensors in the sensor pattern on the CF substrate. Due to the arranging the conductive pads on the array substrate at the positions corresponding to the CF substrate, forming the conductive pads in the transparent conductive layers of the CF substrate and the array substrate, connecting the conductive pads arranged on the color filter substrate with the IC, the resistance of the metal wires being smaller than that of the conductive wires in the transparent conductive layer, the transmission resistance are effectively reduced during the signal transmission, and thereby the heat generated by the transmission resistance are effectively reduced, and heat may be dissipated rapidly.

In addition, after arranging conductive pads at the edges of each line and each column of the sensors in the sensor pattern on the CF substrate and arranging conductive pads on the array substrate at the positions corresponding to those conductive pads on the CF substrate, the arranged conductive pads will not be concentrated on a same area, and thus the preparation process is simple and the integrated case is more stable, which helps to improve the performance and life of the touch devices.

Moreover, the metal wires are such metal wires that are formed from the metal layer on the array substrate. Since the metal wires are made from the metal layer on the array substrate via one-step patterning process, there is not any substantial process step is added, and thus the production process is simplified, and the production cost is effectively reduced.

### BRIEF DESCRIPTION OF THE DRAWINGS

In order to illustrate the technical solution of the embodiments of the invention more clearly, the drawings of the embodiments will be briefly described below. It is obvious that the drawings as described below are only related to some embodiments of the invention, but not limitative of the invention.

FIG. 1a is a top view of the CF substrate structure of the in-cell touch device in the prior art.

FIG. 1b is a top view of the array substrate structure of the in-cell touch device in the prior art.

FIG. 2a is a top view of the CF substrate structure of the in-cell touch device of an embodiment of the present invention.

FIG. 2b is a top view of the array substrate structure of the in-cell touch device of an embodiment of the present invention.

FIG. 3 is a schematic view of the cell after cell assembling of the in-cell touch device of the embodiment of the present invention.

FIG. 4 is a flow diagram of the method for manufacturing the in-cell touch device of the present invention.

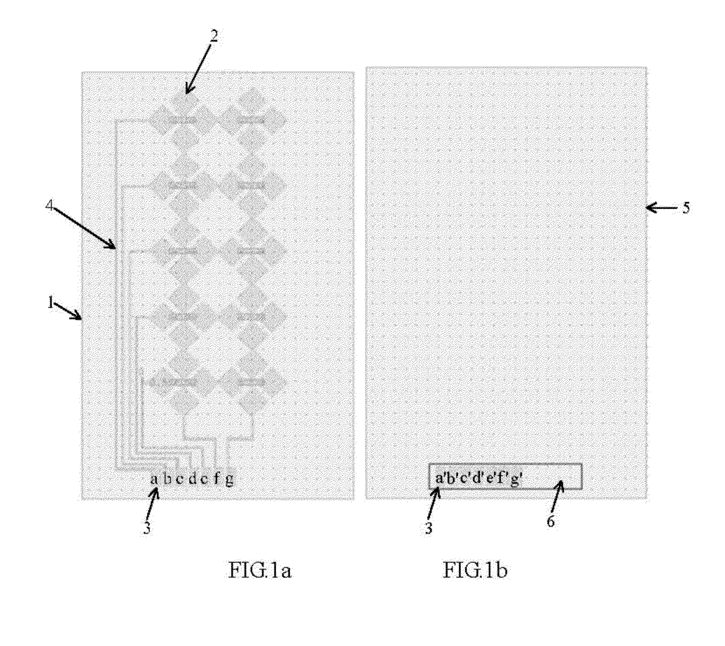

### REFERENCE NUMERALS

1—CF substrate; 2—sensor; 3—ITO conductive pads; 4—circuit wirings of the ITO layer; 5—array substrate; 6—IC; 7—metal wires; 8—conductive guiding material.

### DETAILED DESCRIPTION

In order to make objects, technical details and advantages of the embodiments of the invention apparent, hereinafter, the technical solutions of the embodiments of the invention will be described in a clearly and fully understandable way in connection with the drawings related to the embodiments of the invention. It is obvious that the described embodiments are just a part but not all of the embodiments of the invention.

Unless otherwise defined, the technical terminology or scientific terminology used herein should have the same meaning as commonly understood by one of ordinary skill in the art to which this invention belongs. “First”, “second” and the like used in specification and claims of the patent application of the invention do not show any order, number or importance, but are only used to distinguish different constituent parts. Likewise, terms such “a,” “an,” “the” or the like does not indicate limitation in number, but specifies the presence of at least one. The term such as “comprises,” “comprising,” “comprises,” “comprising”, “contains” or the like means that an element or article prior to this term encompasses element(s) or article(s) listed behind this term and equivalents, but does not preclude the presence of other elements or articles. The term such as “connection,” “connected,” or the like is not limited to physical or mechanical connection, but can comprise electrical connection, whether directly or indirectly. “Upper,” “lower,” “left,” “right” or the like is only used to describe a relative positional relationship, and when an absolute position of the described object is changed, the relative positional relationship might also be changed accordingly.

The present invention will be described in further detail by referring to the specific embodiments and the accompanying drawings.

The in-cell touch device provided in the present invention comprises: a CF substrate, an array substrate, and an IC; wherein conductive pads are arranged on the edges of each line and each column of the sensors in sensor pattern on the CF substrate, and conductive pads are arranged on the array substrate at the positions corresponding to the CF substrate; and wherein the conductive pads are formed in the transparent conductive layers of the CF substrate and the array substrate, the conductive pads arranged on the CF substrate are connected to the conductive pads arranging at the corresponding positions on the array substrate through conductive guiding material, and the conductive pads arranged on the array substrate are connected to the IC through metal wires.

Wherein the sensors are used to communicate signals with the IC in turns through the conductive pads arranged on the CF substrate, the conductive guiding material, the conductive pads arranged on the array substrate, and the metal wires.

Herein, the sensor pattern refers to patterns formed by all the sensors on the CF substrate.

The material of the transparent conductive layer may be ITO or indium zinc oxide (IZO).

The conductive pads may be arranged at the edges of each line and each column of the sensors in the sensor pattern on the CF substrate by one-step patterning process; and correspondingly, the conductive pads may be arranged at the corresponding positions on the array substrate by one-step pattering process.

The positions for arranged the conductive pads may be determined based on the dimensions of the panels and the sizes of the frames formed by the CF and array substrates when arranging the conductive pads on the CF substrate.

The IC circuit may be bound on the array substrate.

The metal wires may be the metal wires formed from the metal layer on the array substrate, and the material of the metal layer may be selected from Mo, Al, AiNd, or AlNdMo. Wherein, the metal wires may be formed on the metal layer by one-step patterning process.

In a way of example, the conductive pads are arranged at both left and right edges of each line of the sensors in the sensor pattern on the CF substrate, wherein, the left edge refers to the left edge of the sensor pattern when looking at the CF substrate from top, and correspondingly, the right edge refers to the right edge of the sensor pattern when looking at the CF substrate from top.

In the in-cell touch device provided in the present invention, the length of the circuit wirings of the transparent conductive layer on the CF substrate may be effectively reduced due to the arrangement the conductive pads at the edges of each line and each column of the sensors in the sensor pattern on the CF substrate. Owning to the arrangement of the conductive pads on the array substrate at the positions corresponding to the CF substrate, the formation of the conductive pads in the transparent conductive layers of the CF substrate and the array substrate, the connection of the conductive pads arranged on the array substrate and the IC by adopting the metal wires, the resistance of the metal wires being smaller than that of the conductive wires in the transparent conductive layer, in this way, the transmission resistance during the signal transmission is effectively reduced, and thereby the heat generated by the transmission resistance is effectively reduced, and further, heat may be dissipated rapidly.

In addition, after arranging conductive pads at the edges of each line and each column of the sensors in the sensor pattern on the CF substrate, and arranging conductive pads at the positions corresponding to those conductive pads on the CF substrate on an array substrate, the arranged conductive pads would not unduly concentrate in an area, so that the preparation process is simple and the integrated case is more stable, which helps to improve the performance and life of the touch devices.

The preferred embodiments of the present invention will be described with reference to the drawings.

In the present embodiment, the metal layer is a Mo layer, and correspondingly, the metal wires are Mo wires.

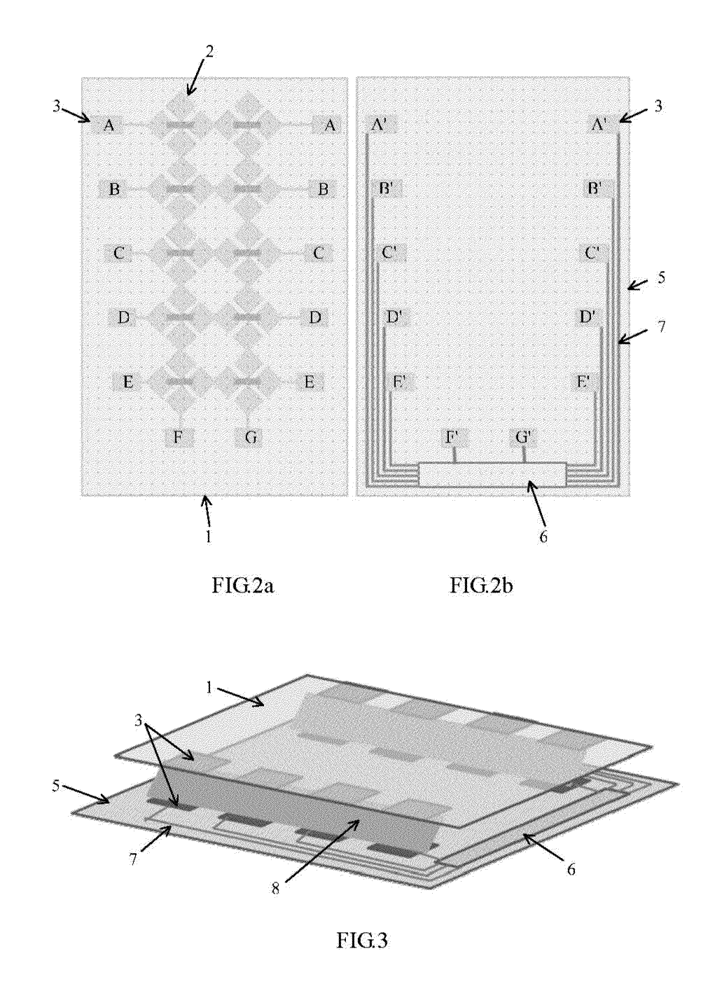

FIG. 2a is a structure diagram of the CF substrate of the in-cell touch device of the present embodiment. In the embodiment, the material of the transparent conductive layer is ITO, and correspondingly, the formed conductive pads are referred to as ITO conductive pads. As shown in FIG. 2a, a plurality of the sensors are arranged on the CF substrate 1, and the ITO conductive pads 3 with numerals of A, B, C, D, and E are symmetrically arranged at the left and right edges of each line of the sensors 2 on the CF substrate, and meanwhile, two ITO conductive pads 3 with numerals of F and G are arranged at the edges of each column of the sensor 2 on the CF substrate.

FIG. 2b is a structure diagram of the array substrate of the in-cell touch device in the present invention. As shown in FIG. 2b, the ITO conductive pads 3 with numerals of A′, B′, C′, D′, E′, F′, and G′ are arranged on the array substrate 5 at the positions corresponding to those conductive pads on the CF substrate 1. The IC 6 is bounded on the array substrate 5, and the ITO conductive pads 3 arranged on the array substrate 5 are connected with the IC 6 by the metal wires 7 of the metal layer.

FIG. 3 is a schematic view of the cell after cell assembling of the in-cell touch device of the embodiment. As shown in FIG. 3, the ITO conductive pads 3 arranged on the CF substrate 1 and the ITO conductive pads 3 arranged on the array substrate 5 at the positions corresponding to those ITO conductive pads 3 on the CF substrate 1 are connected by the conductive guiding material 8. The sensors 2 communicate signals with the IC 6 in turns through the ITO conductive pads 3 arranged on the CF substrate, the conductive guiding material 8, the ITO conductive pads 5 arranged on the array substrate, and the metal wires 7.

Wherein, the metal wires 7 are produced from the metal layer on the array substrate 5 by one-step pattering process (such as, coating, exposure, and etching), that is, the exposure and etching of the metal wires 7 may be performed in the process of the exposure and etching of the metal layer, and thus no substantial process step is added.

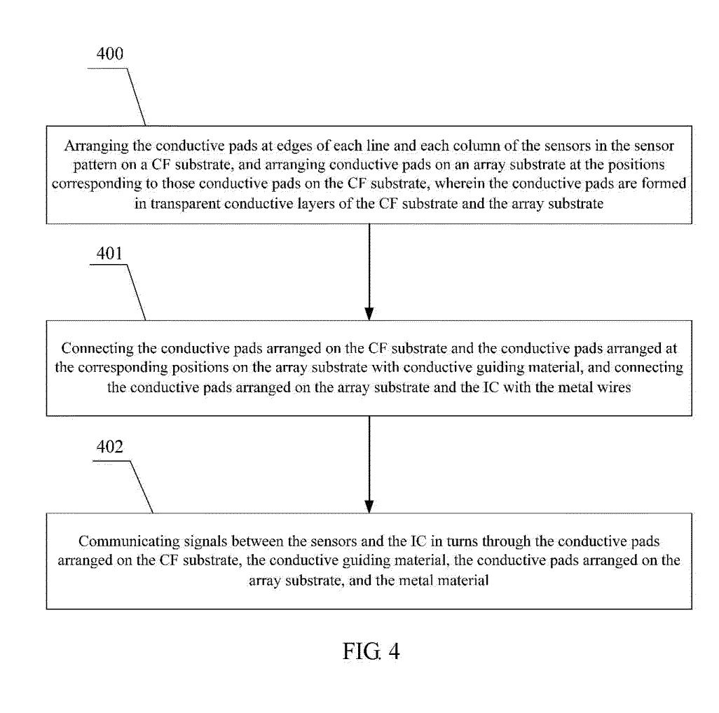

Based on the above in-cell touch device, the present invention further provides a method for manufacturing the in-cell touch device, and the method will be described below with reference to FIG. 4.

In STEP 400, the conductive pads are arranged at the edges of each line and each column of the sensors in the sensor pattern on a CF substrate, and conductive pads are arranged on an array substrate at the positions corresponding to those conductive pads on the CF substrate, wherein the conductive pads are formed in transparent conductive layers of the CF substrate and the array substrate.

Herein, the sensor pattern refers to: the pattern formed by all the sensors on the CF substrate.

The material of the transparent conductive layer may be ITO or IZO.

Arranging the conductive pads at the edges of each line and each column of the sensors in the sensor pattern on the CF substrate may be realized by the one-step patterning process; and correspondingly, arranging the conductive pads at the corresponding positions on the array substrate may be realized by the one-step pattering process.

Arranging the conductive pads at the edges of each line and each column of the sensors in the sensor pattern on the CF substrate comprises: arranging the conductive pads at both the left and right edges of each line of the sensors in the sensor pattern on the CF substrate, wherein, the left edge refers to the left edge of the sensor pattern when looking at the CF substrate from top, and correspondingly, the right edge refers to the right edge of the sensor pattern when looking at the CF substrate from top.

In STEP 401, the conductive pads arranged on the CF substrate are connected to the conductive pads arranged at the corresponding positions on the array substrate with conductive guiding material, and the conductive pads arranged on the array substrate are connected to the IC with the metal wires.

Herein, the IC is bound on the array substrate.

The metal wires may be the metal wires formed from the metal layer on the array substrate. The metal layer material may be selected from Mo, Al, AlNd or AlNdMo. Wherein, the metal wires may be formed on the metal layer by the one-step patterning process.

In STEP 402, the sensors communicate signals with the IC in turns through the conductive pads arranged on the CF substrate, the conductive guiding material, the conductive pads arranged on the array substrate, and the metal material.

The above states only the specific embodiments of the present invention, but the scope of the present invention is not limited thereto. Any modifications or alternations which those skilled in the art can easily conceive within the scope disclosed in the present invention shall fall into the protection scope of the present invention. Therefore, the scope of protection of the present invention should be determined by the attaching claims.

1-10. (canceled)

11. An in-cell touch device, comprising: a color filter substrate, an array substrate, and an integration circuit,
wherein conductive pads are arranged on edges of each line and each column of the sensors in the sensor pattern on the color filter substrate, and conductive pads are arranged on the array substrate at the positions corresponding to those conductive pads on the color filter substrate, wherein the conductive pads are formed in the transparent conductive layers of the color filter substrate and the array substrate, the conductive pads arranged on the color filter substrate are connected to the conductive pads at the corresponding positions on the array substrate through conductive guiding material, and the conductive pads arranged on the array substrate are connected to the integration circuit by metal wires, and
wherein the sensors are used for communicating signals with the integrate circuit in turns through the conductive pads arranged on the color filter substrate, the conductive guiding material, the conductive pads arranged on the array substrate, and the metal wires.

12. The in-cell touch device according to claim 11, wherein the conductive pads are arranged at both the left and right edges of each line of the sensors in the sensor pattern on the color filter substrate.

13. The in-cell touch device according to claim 11, wherein the integration circuit is bound on the array substrate.

14. The in-cell touch device according to claim 12, wherein the integration circuit is bound on the array substrate.

15. The in-cell touch device according to claim 11, wherein the metal wires are the metal wires formed from the metal layer on the array substrate.

16. The in-cell touch device according to claim 12, wherein the metal wires are the metal wires formed from the metal layer on the array substrate.

17. The in-cell touch device according to claim 13, wherein the metal wires are the metal wires formed from the metal layer on the array substrate.

18. The in-cell touch device according to of claim 14, wherein the metal wires are the metal wires formed from the metal layer on the array substrate.

19. The in-cell touch device according to claim 15, wherein the material of the metal layer is selected from Mo, Al, AiNd, or AlNdMo.

20. A method for manufacturing an in-cell touch device comprising:
arranging conductive pads on edges of each line and each column of the sensors in the sensor pattern on a color filter substrate, and arranging conductive pads on an array substrate at the positions corresponding to those conductive pads on the color filter substrate, the conductive pads being formed in transparent conductive layers of the color filter substrate and the array substrate;
connecting the conductive pads arranged on the color filter substrate and the conductive pads arranged at the corresponding positions on the array substrate with conductive guiding material, and connecting the conductive pads arranged on the array substrate and the integration circuit with metal wires, and
communicating signals from the sensors to the integration circuit in turns through the conductive pads arranged on the color filter substrate, the conductive guiding material, the conductive pads arranged on the array substrate, and the metal material.

21. The method according to claim 20, wherein the arranging the conductive pads at the edges of each line and each column of the sensors in the sensor pattern on the color filter substrate comprises:
arranging the conductive pads at both left and right edges of the each line of the sensors in the sensor pattern on the color filter substrate.

22. The method according to claim 20, wherein the method further comprises:
determining the positions of the arranged conductive pads based on the dimensions of the panels and the sizes of the frames formed by the color filter substrate and the array substrates when arranging the conductive pads on the color filter substrate.

23. The method according to claim 21, wherein the method further comprises:
determining the positions of the arranged conductive pads based on the dimensions of the panels and the sizes of the frames formed by the color filter substrate and the array substrates when arranging the conductive pads on the color filter substrate.

24. The method according to claim 20, wherein the metal wires are the metal wires formed from the metal layer on the array substrate.

25. The method according to claim 21, wherein the metal wires are the metal wires formed from the metal layer on the array substrate.

26. The method according to claim 22, wherein the metal wires are the metal wires formed from the metal layer on the array substrate.

27. The method according to claim 23, wherein the metal wires are the metal wires formed from the metal layer on the array substrate.

28. The method according to claim 24, wherein the material of the metal layer is selected from Mo, Al, AlNd or AlNdMo.
